(19) United States
(12) Patent Application Publication
(10) Pub. No.: US 2025/0107107 A1
(43) Pub. Date: Mar. 27, 2025

(54) STACKED MEMORY LAYERS WITH UNIFORM ACCESS

(71) Applicant: Intel Corporation, Santa Clara, CA (US)

(72) Inventors: Abhishek A. Sharma, Portland, OR (US); Sagar Suthram, Portland, OR (US); Wilfred Gomes, Portland, OR (US); Pushkar Sharad Ranade, San Jose, CA (US); Anand S. Murthy, Portland, OR (US); Tahir Ghani, Portland, OR (US)

(73) Assignee: Intel Corporation, Santa Clara, CA (US)

(21) Appl. No.: 18/471,402

(22) Filed: Sep. 21, 2023

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2225/06541; H01L 2924/1431; H01L 2924/1437

(57) ABSTRACT

An IC device may include memory layers over a logic layer. A memory layer may include memory arrays and one or more peripheral circuits coupled to the memory arrays. A memory array may include memory cells arranged in rows and columns. A row of memory cells may be associated with a word line. A column of memory cells may be associated with a bit line. The logic layer includes one or more logic circuits that can control data read operations and data write operations of the memory layers. The logic layer may also include a power interconnect, which facilitates power delivery to the memory layers, and a signal interconnect, which facilitates signal transmission within the IC device. The IC device may further include vias that couple the memory layers to the logic layer. Each via may be connected to one or more memory layers and the logic layer.

### BACKGROUND

Integrated circuit (IC) devices with memory circuitry are important to the performance of modern system-on-a-chip (SoC) technology. IC fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device including memory layers over a logic layer, according to some embodiments of the disclosure.

FIG. 2 illustrates an IC device including a stack of memory devices, according to some embodiments of the disclosure.

FIG. 3 illustrates an IC device including a logic die with a power interconnect and a signal interconnect for power and signal delivery and a memory die over the logic die, according to some embodiments of the disclosure.

FIG. 4 illustrates an IC device including a FEOL section and a BEOL section, according to some embodiments of the disclosure.

FIG. 5 shows a transistor with nanoribbons, according to some embodiments of the disclosure.

FIG. 6A illustrates semiconductor regions of a transistor in a memory die, according to some embodiments of the disclosure.

FIG. 6B illustrates semiconductor regions of a transistor in a logic die, according to some embodiments of the disclosure.

FIG. 7 illustrates an IC device including a stack of wafers, according to some embodiments of the disclosure.

FIG. 8 is an electric circuit diagram of an example memory cell, according to some embodiments of the present disclosure.

FIG. 9 provides a top-down plan view of one example implementation of the memory cell in FIG. 8, according to some embodiments of the present disclosure.

FIGS. 10A and 10B are top views of a wafer and dies that can facilitate stacked memory layers with uniform access, according to some embodiments of the disclosure.

FIG. 11 is a side, cross-sectional view of an example IC package that may include stacked memory layers with uniform access, according to some embodiments of the disclosure.

FIG. 12 is a cross-sectional side view of an IC device assembly that may include components having stacked memory layers with uniform access, according to some embodiments of the disclosure.

FIG. 13 is a block diagram of an example computing device that may include one or more components with stacked memory layers with uniform access, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to static random-access memory (SRAM). Other embodiments of the present disclosure may refer to dynamic random-access memory (DRAM). However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays.

A memory cell is a fundamental building block of computer memory devices used to store and retrieve data. It is a small unit of storage that can hold a single bit of information, which can be either a 0 or a 1. Memory cells are organized in a grid-like structure to form memory arrays. A SRAM cell may include a plurality of transistors for storing a bit value or a memory state (e.g., logic “1” or “0”) of the memory cell and one or more access transistors for controlling access to the memory cell (e.g., access to write data to the cell or access to read data from the cell). SRAM is used in many different computer products and further improvements are always desirable. A memory array also includes word lines and bit lines coupled to memory cells. A word line can be used to control the access to a specific row of memory cells in the memory array. When the word line is activated, it enables the data stored in the selected row to be read or modified. A bit line can couple the memory cells in the memory array to the memory control circuitry. A bit line can be used for reading and writing data.

Memory arrays can be arranged in memory layers. A memory layer may be a die. Memory layers may be arranged in a stack. Performance of memory devices (e.g., memory bandwidth) is often limited by the number of memory arrays that can be implemented in a memory layer or the number of memory layers that can be stacked in the available memory area. For example, currently available memory devices often require flow control circuits in memory dies. With the presence of the flow control circuits, the space for arranging memory arrays in a memory die is limited. As another example, currently available memory devices require power delivery structures in memory dies. The power delivery structures are usually implemented in BEOL metal layers, which can make the memory die “thicker” so that the number of memory dies that can be arranged in the available memory would be limited.

Embodiments of the present disclosure may improve on at least some of the challenges and issues described above by providing stacked memory layers with uniform access. For example, a stack of memory layers may be coupled to a logic layer through vias, such as through-silicon vias (TSVs). The logic layer may also be referred to as a compute layer or compute logic layer. The logic layer includes power structures and power can be delivered from the logic layer to the memory layer through the vias so that power structures in the memory layers are not required. Also, the vias can facilitate signal transmission between the memory layers and the logic layer. A via may couple multiple memory layers to the logic layer. That way, the logic layer can have uniform access to the memory layers. Compared with currently available memory devices, a memory device including stacked memory layers with uniform access can have better performance as more memory cells can be arranged in the memory device.

In various embodiments of the present disclosure, an IC device (which may also be referred to as an IC assembly) may include a plurality of memory layers over a logic layer. A memory layer may include a plurality of memory arrays and one or more peripheral circuits coupled to the memory arrays. The number of memory arrays may vary. A memory array may include memory cells arranged in rows and columns. A row of memory cells may be associated with a word line. A column of memory cells may be associated with a bit line. A memory array may also include other components, such as sense amplifier, row decoder, column decoder, buffer, or some combination thereof. The memory layer may have one or more peripheral circuits, which may be arranged at portions of the memory layer that are not taken by memory arrays. The logic layer includes one or more logic circuits that can control operations for reading data from the memory layers or writing data into the memory layers. The logic layer may also include power delivery components (e.g., power interconnect, power vias, power capacitor, etc.), which facilitate power delivery to the memory layers, and signal delivery component (e.g., signal interconnect, signal via, etc.), which facilitates signal transmission within the IC device. Each memory layer may be a memory die or memory wafer. The logic layer may be a logic die or logic wafer.

Given the presence of the power delivery components and signal delivery components, the logic layer may have more BEOL metal layers than the metal layer. Also, the logic layer may include transistors that are different from transistors in the memory layers. The architecture of a transistor in the logic layer may be different from the architecture of a transistor in the memory layer. In an example, a transistor in the logic layer may have a nanoribbon semiconductor structure versus a transistor in the memory layer may have a fin semiconductor structure. One or more dimensions of a semiconductor structure of a transistor in the logic layer may be larger than corresponding dimensions of a semiconductor structure of a transistor in the memory layer. A transistor in the logic layer may include a different workfunction material from a transistor in the memory layer.

The IC device may further include vias that couple the memory layers to the logic layer. The vias may function as channels between the memory layers and the logic layer. Each via may be connected to one or more memory layers and the logic layer. For instance, a via may be connected to peripheral circuits of multiple memory layers and to one or more circuits or devices in the logic layer. Signals can be transmitted to or from these memory layers through the via, e.g., in the same signal transmission cycle. The vias may include one or more power vias for power delivery and one or more signal vias for signal delivery.

It should be noted that, in some settings, the term “nanoribbon” has been used to describe an elongated semiconductor structure that has a substantially rectangular transverse cross section (e.g., a cross section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide.

The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

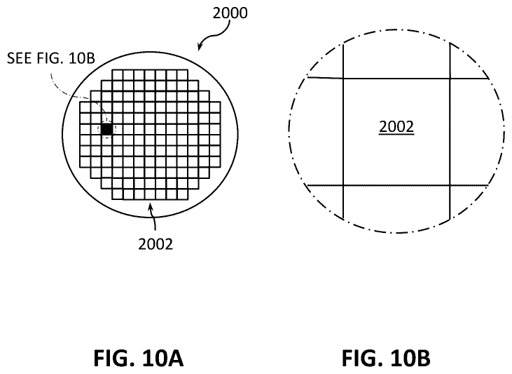

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 10A and 10B, such a collection may be referred to herein without the letters, e.g., as “FIG. 10.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross section of a device to detect the shape and the location of various device elements described herein using e.g., Physical Failure Analysis (PFA) would allow determination of presence of stacked memory layers with uniform access as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various stacked memory layers with uniform access as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

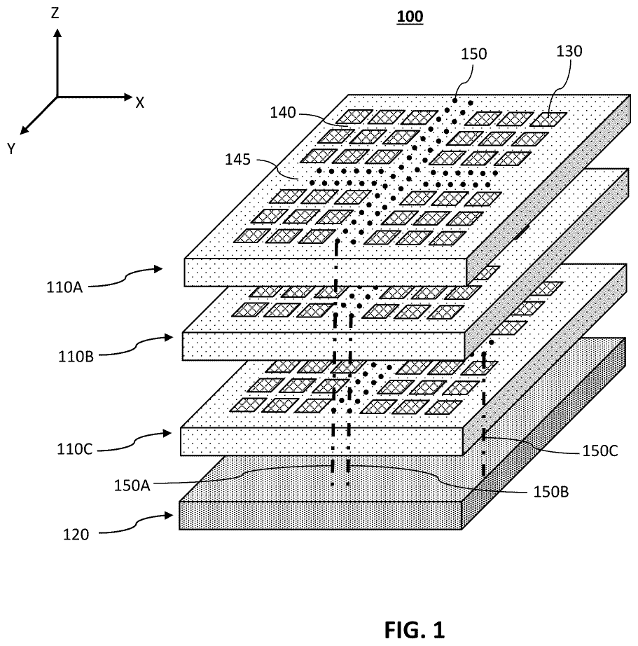

FIG. 1 illustrates an IC device 100 including memory layers 110A-110C over a logic layer 120, according to some embodiments of the disclosure. The memory layers 110A-110C are collectively referred to as “memory layers 110” or “memory layer 110.” A memory layer 110 or the logic layer 120 may be in an X-Y plane. The memory layers 110 are stacked over each other, and the stack of memory layers 110 is over the logic layer 120. The IC device 100 further includes a group of vias 150 (individually referred to as “via 150”). The group of vias 150 includes a via 150A, a via 150B, a via 150C, and other vias 150. In other embodiments, the IC device 100 may include fewer, more, or different components. For instance, the IC device 100 may include a different number of memory layers 110. Also, the arrangement of the components of the IC device 100 (e.g., the positions of the components) may be different. The IC device 100 may also be referred to as an IC assembly.

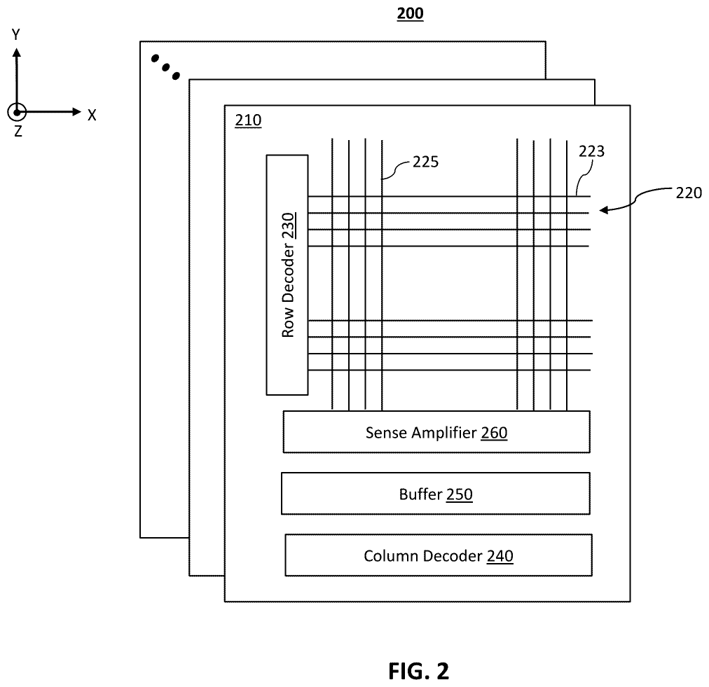

Each memory layer 110 includes memory devices 130 and peripheral circuits 140 and 145. A memory device 130 may include a memory array. A memory array may be an array of memory cells, in which the memory cells may be arranged in rows or columns. For instance, memory cells may be organized in a grid-like structure. A memory cell may include one or more memory elements and one or more access transistors. A memory element may store information. An access transistor may be coupled to the memory element and controls access to the memory element. A memory array may also include bit lines and word lines coupled to the memory cells. A bit line can couple the memory cells in the memory array to a control device, e.g., a control device in the peripheral circuit 140 or 145, a control device in the logic layer 120, and so on. A bit line can be used for reading and writing data. A word line can be used to control the access to a specific row of memory cells in the memory array. When the word line is activated, it enables the data stored in the selected row to be read or modified. For the purpose of illustration, FIG. 1 shows four groups of memory arrays in the memory layer 110, and each group has nine memory arrays. In other embodiments, the memory layer 110 may include a different number of memory arrays. Also, memory arrays in the memory layer 110 may be arranged differently. More details regarding memory array are described below in conjunction with FIG. 2.

The peripheral circuits 140 and 145 are circuits at peripheral areas of the memory layer 110. A peripheral area may be an area having no memory devices 130. The peripheral circuits 140 and 145 may include peripheral devices that can facilitate operations of the memory devices 130. For instance, the peripheral circuit 140 or 145 may be used for accessing, controlling, or testing the memory cells. The peripheral circuits 140 and 145 may be arranged at spaces in the memory layer 110 that are not taken by the memory devices 130. The peripheral circuit 140 or 145 may be at least partially surrounded by memory devices 130. For instance, at least part of the peripheral circuit 140 or 145 may be between two or more memory devices 130. Even though FIG. 1 shows a single peripheral circuit 140 and a single peripheral circuit 145, the memory layer 110 may include one or more other peripheral circuits. Also, the locations of peripheral circuits may be different.

In some embodiments, the peripheral circuit 140 may be a local peripheral circuit, while the peripheral circuit 145 may be a global peripheral circuit. A global peripheral circuit may be coupled to more memory devices 130 than a local peripheral circuit. For instance, a local peripheral circuit may be coupled to a single memory array or a small number of memory devices 130 (e.g., the memory devices 130 surrounding the local peripheral circuit), while a global peripheral circuit may be coupled to a plurality of memory devices 130 (e.g., one or more groups of memory arrays). In some embodiments, the memory layer 110 may include a single global peripheral circuit that can facilitate operations of all the memory devices 130 in the memory layer 110. In some embodiments, a global peripheral circuit may facilitate operations of memory devices 130 through one or more local peripheral circuit coupled to the memory devices 130.

The logic layer 120 includes various circuits and devices to drive and control the memory layers 110. For example, the logic layer 120 may provide power and signal (e.g., read request, write request, read data, write data, etc.) to the memory layers 110, e.g., through the vias 150. A logic circuit or device in the logic layer 120 may be coupled to the peripherical circuit 140 or 145. For instance, a signal from the logic layer 120 may be transmitted to the peripherical circuit 140 or 145 for a data read operation or a data write operation. Also, the logic layer 120 may facilitate delivery of power to the peripherical circuits 140 and 145 and the memory devices 130. In some embodiments, the logic layer 120 may facilitate global power delivery to the memory layers 110, and power delivery components may be avoided in the memory layers 110. In some embodiments, the logic layer 120 may include one or more processing units (e.g., central processing unit (CPU), graphics processing unit (GPU), etc.) that can generate data read or write signals, generate data to be written into memory cells in the memory layers 110, process data read from memory cells in the memory layers 110, and so on.

In some embodiments, the logic layer 120 may be provided in a FEOL layer and in one or more lowest BEOL layers (i.e., in one or more BEOL layers which are closest to the FEOL layer), while the memory layers 110 may be provided in higher BEOL layers (i.e., in one or more BEOL layers which are further to the FEOL layer than the logic layer 120). A BEOL layer may be, or may include, a metal layer. A BEOL layer may be used to interconnect the various inputs and outputs of the logic devices in the logic layer 120 and/or of the memory cells in the memory layers 110. In some embodiments, a BEOL layer may include one or more via portions and one or more trench portions. A trench portion of a BEOL layer may be configured for transferring signals and power along electrically conductive (e.g., metal) lines (also sometimes referred to as “tracks”) extending in the X-Y plane (e.g., in the x- or y-directions). A via portion of a BEOL layer may be configured for transferring signals and power through electrically conductive vias extending in the Z-direction, e.g., to any of the adjacent BEOL layers above or below. Vias may connect electrically conductive structures (e.g., metal lines or other vias) from one BEOL layer to electrically conductive structures of one or more adjacent BEOL layers. A BEOL layer may include one or more conductive materials, e.g., copper (Cu), aluminum (AI), tungsten (W), or cobalt (Co), or metal alloys, or more generally, patterns of an electrically conductive material, formed in an insulating medium. The insulating medium may include any suitable electrical insulators, such as silicon oxide, carbon-doped silicon oxide, silicon carbide, silicon nitride, aluminum oxide, and/or silicon oxynitride.

The vias 150 facilitate delivery of power from the logic layer 120 to the memory layers 110. The vias 150 also facilitate delivery of signals (e.g., read request, read data, write request, write data, etc.) between the logic layer 120 and the memory layers 110A. A via 150 may include one or more conductive structures, e.g., metal structures. Each via 150 may have a longitudinal axis along the Z axis, which may be perpendicular to the X-Y plane of a memory layer 110 or the logic layer 120. In some embodiments, the length of a via 150 along the Z axis may be greater than the thickness of a memory layer 110 along the Z axis. A via 150 may penetrate from a substrate of a memory layer 110 or the logic layer 120. In some embodiments, a via 150 may be a through-silicon via.

A via 150 may extend from a memory layer 110 to the logic layer 120. The via 150 may pass one or more other memory layers 110 between the memory layer 110 and the logic layer 120. As an example, the via 150A couples the memory layers 110A-110C to the logic layer 120. Power and signals can be transferred from the logic layer 120 to the memory layers 110A-110C. Also, signals can be transferred from the memory layers 110A-110C to the logic layer 120. For instance, the via 150A can facilitate transmission of a first signal from the memory layer 110A, a second signal from the memory layer 110B, and a third signal from the memory layer 110C to the logic layer 120. The three signals may be sent to the logic layer 120 together. Similarly, the logic layer 120 may send a signal to each of the memory layers 110A-110C using the via 150A. The via 150A may be connected to peripherical circuits of the memory layers 110A-110C.

As another example, the via 150B couples the memory layers 110B and 110C to the logic layer 120. The via 150B is not coupled to the memory layer 110A. Power and signals can be transferred from the logic layer 120 to the memory layers 110B and 110C. Also, signals can be transferred from the memory layers 110B and 110C to the logic layer 120. For instance, the via 150B can facilitate transmission of a first signal from the memory layer 110B and a second signal from the memory layer 110C to the logic layer 120. The two signals may be sent to the logic layer 120 together. Similarly, the logic layer 120 may send a signal to each of the memory layers 110B and 110C using the via 150B. The via 150A may be connected to peripherical circuits of the memory layers 110B and 110C. As yet another example, the via 150C couples the memory layer 110C to the logic layer 120. The via 150B is not coupled to the memory layer 110A or 110B. Power and signals can be delivered from the logic layer 120 to the memory layer 110C. Also, signals can be transferred from the memory layer 110C to the logic layer 120. Other vias 150 may be coupled to different combinations of memory layers. For instance, a via 150 may be coupled to the memory layer 110A but not to the memory layer 110B or 110C, another via 150 may be coupled to the memory layer 110B but not to the memory layer 110A or 110C, another via 150 may be coupled to the memory layers 110A and 110C but not to the memory layer 110B, and so on.

In some embodiments, a via 150 may have an end connected to a memory layer 110 and another end connected to the logic layer 120. The via 150 may also be connected to one or more other memory layers 110 so that the via 150 can facilitate power or signal delivery between the logic layer 120 with more than one memory layers 110. An example via 150 may be connected to all the memory layer 110 in the IC device 100. Another example via 150 may be connected to some of the memory layer 110 in the IC device 100. Yet another example via 150 may be connected to a single memory layer 110 in the IC device 100. For the purpose of illustration, the vias 150 in FIG. 1 are arranged in two rows and two columns. In other embodiments, a memory layer 110 may include a different number of vias. Also, vias may be arranged differently.

The vias 150 may include power vias for transferring power between layers and signal vias for transferring data signals between layers. In some embodiments, cross-sectional dimensions (e.g., diameters) and a pitch (e.g., defined as a center-to-center distance) of power vias are larger than cross-sectional dimensions and a pitch of signal vias. For example, the pitch of the power vias extending through the logic layer 120 and the memory layers 110 may be between about 10 and 25 micron, e.g., between about 15 and 20 micron, while the pitch of the signal vias may be between about 2 and 12 micron, e.g., between about 4 and 9 micron. In some embodiments, the cross-sectional dimensions (e.g., diameters) of the power vias may be between about 7 and 11 micron, e.g., about 9 micron, while the cross-sectional dimensions of the signal vias may be between about 2 and 4 micron, e.g., about 3 micron. In some embodiments, the cross-sectional dimension may be between about 45%-55% of the pitch.

Even though not shown in FIG. 1, the IC device 100 may also include bonding interfaces between the memory layers 110 and a bonding interface between the memory layer 110C and the logic layer 120. The memory layers 110 and the logic layer 120 may be bonded together through the bonding interfaces. The vias 150 may penetrate through at least some of the bonding interfaces. The bonding between two memory layers 110 or between the memory layer 110C and the logic layer may be performed using insulator-insulator bonding, e.g., as oxide-oxide bonding, where an insulating material of a first IC structure (e.g., an IC structure in a memory layer 110) is bonded to an insulating material of a second IC structure (e.g., an IC structure in another memory layer 110 or in the logic layer 120). In some embodiments, a bonding material may be present in between the faces of the first and second IC structures that are bonded together. The vias 150 may extend through the bonding material and into the surrounding layers.

In some embodiments, a memory layer 110 may be a memory die, e.g., a die in a memory wafer. The logic layer 120 may be a logic die, e.g., a die in a logic wafer. The dies may be physically bonded through hybrid bonding. Hybrid bonding involves bonding dies with ICs formed thereon. The dies may be formed by different processes and then combined, thus achieving various functionalities (e.g., logic and memory) in the bonded combination.

A bonding material may be used to bond two layers/dies together. To bond the two layers/dies together, the bonding material may be applied to one or both faces of the first and second IC structures that should be bonded (e.g., to the lower face of the memory layer 110C and/or the upper face of the logic layer 120). After the bonding material is applied, the first and second IC structures are put together, possibly while applying a suitable pressure and heating up the assembly to a suitable temperature (e.g., to relatively low temperatures, e.g., between about 50 and 200 degrees Celsius) for a duration of time. In some embodiments, the bonding material may be an adhesive material that ensures attachment of the first and second IC structures to one another. In some embodiments, the bonding material may be an etch-stop material. In some embodiments, the bonding material may be both an etch-stop material and have suitable adhesive properties to ensure attachment of the first and second IC structures to one another.

In some embodiments, the bonding material may have a thickness between 50 nm and 1000 nm. In some embodiments, the bonding material has a thickness between 100 nm and 300 nm, e.g., the bonding material has a thickness of about 200 nm. In some embodiments, the bonding material includes silicon in combination with one or more of oxygen, nitrogen, and carbon. The bonding material may be a polyimide, an epoxy polymer, or any underfill material. The bonding material may have a dielectric constant in the range of 1.5 to 8. In some embodiments, the bonding material has a dielectric constant that is less than 3.9, e.g., in the range of 1.5 to 3.9.

In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using an etch-stop material at the interface that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the first and second IC structures together. In addition, an etch-stop material at the interface between the first and second IC structures that includes include silicon, nitrogen, and carbon, where the atomic percentage of any of these materials may be at least 1%, may be advantageous in terms of improving etch-selectivity of this material with respect to etch-stop materials that may be used in different of the first and second IC structures.

In some embodiments, no bonding material may be used, but there will still be a bonding interface resulting from the bonding of the layers to one another. Such a bonding interface may be recognizable as a seam or a thin layer in the microelectronic assembly, using, e.g., selective area diffraction (SED), even when the specific materials of the insulators of the first and second IC structures that are bonded together may be the same, in which case the bonding interface would still be noticeable as a seam or a thin layer in what otherwise appears as a bulk insulator (e.g., bulk oxide) layer.

The illustration of FIG. 1 is intended to provide a general orientation and arrangement of various layers with respect to one another, and, unless specified otherwise in the present disclosure, includes embodiments of the IC device 100 where portions of elements described with respect to one of the layers shown in FIG. 1 may extend into one or more, or be present in, other layers. For example, the IC device 100 may include a different number of memory layers. Also, the position of the logic layer 120 relative to the memory layers 110 may be different. For instance, the logic layer 120 may be above the memory layers 110 or may be between the memory layers 110.

FIG. 2 illustrates an IC device 200 including a stack of memory devices 210, according to some embodiments of the disclosure. The IC device 200 may also be referred to as an IC assembly. For the purpose of illustration, FIG. 2 shows three memory devices 210 in the IC device 200. In other embodiments, the IC device 200 may include a different number of memory devices 210.

The memory devices 210 (individually referred to as “memory device 210”) are stacked over each other along the X axis. A memory device 210 may be an example of a memory device 130 in FIG. 1. A memory device 210 may be in a memory layer, e.g., a memory layer 110 in FIG. 1. Different memory devices 210 in the IC device 200 may be in different memory layers. Each memory device 210 includes a memory array 220, a row decoder 230, a column decoder 240, a buffer 250, and a sense amplifier 260. In other embodiments, a memory device 210 may include fewer, more, or different components. In some embodiments, the row decoder 230, column decoder 240, buffer 250, and sense amplifier 260 in a memory device 210 may be local to the memory array 220 in the same memory device 210, i.e., they are coupled to the memory array 220 in the same memory device 210 but are not coupled to memory arrays in other memory devices 210. In some embodiments, the memory device 210 may be referred to as a memory array, which includes the row decoder 230, column decoder 240, buffer 250, and sense amplifier 260 in addition to the memory cells, word lines 223, and bit lines 225.

The memory array 220 includes word lines 223 (individually referred to as “word line 223”), bit lines 225 (individually referred to as “bit line 225”), and a plurality of memory cells. A memory cell may be coupled to a bit line 225 and a word line 223. In some embodiments, the memory cells in the memory array 220 are arranged in rows and columns. A row of memory cells may be coupled to a word line 223. The word line 223 may be used to access the memory cells in the row. For instance, when the word line 223 is activated, the row of memory cells may be selected and accessed for data read operations or data write operations. The word lines 223 may also be referred to as row select lines. A column of memory cells may be connected to a bit line 225. The bit line 225 may be used to access the memory cells in the column. For instance, when the bit line 225 is activated, the column of memory cells may be selected and accessed for data read operations or data write operations. In some embodiments, each column of memory cells is connected to two bit lines 225: a first bit line 225 and a second bit line 225 that is the inverse of the first bit line 225. A bit of data may be stored in a column of memory cells.

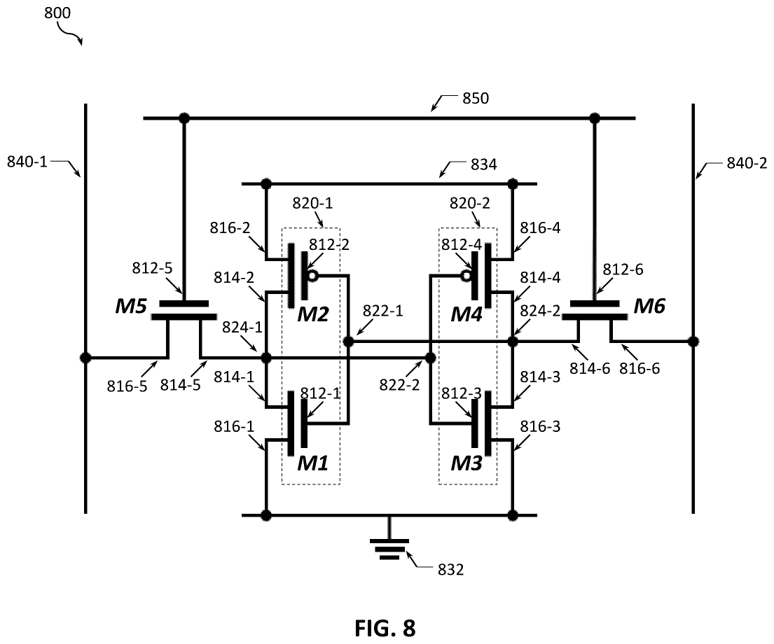

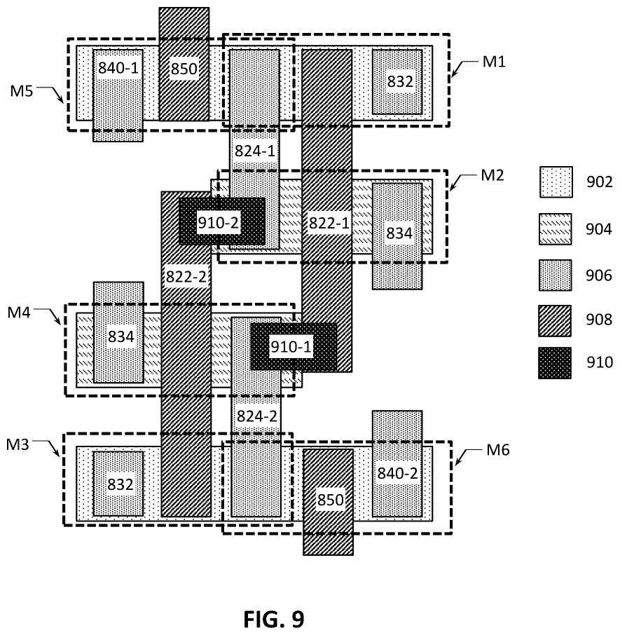

In some embodiments, a memory cell may include one or more transistors. A transistor in a memory cell may receive power from a logic layer, such as the logic layer 120. For instance, an electrode over the source or drain region of the transistor may be coupled to a power via (an example of which may be a via 150 in FIG. 1), and the power via may be coupled to a power interconnect in the logic die. Additionally or alternatively, the transistor may receive a signal from the logic layer. For instance, a gate electrode in the transistor may be coupled to a signal via (an example of which may be a via 150 in FIG. 1), and the signal via may be coupled to a signal interconnect in the logic die. For the purpose of simplicity and illustration, the memory cells are not shown in FIG. 2. More details regarding memory cells are described below in conjunction with FIGS. 8 and 9.

The row decoder 230 selects which rows of memory cells to be accessed based on memory addresses received from a logic circuit, e.g., a circuit in the logic layer 120. In some embodiments, the row decoder 230 may receive an input signal with information indicating a memory address. The row decoder 230 may decode the memory address and select the row(s) corresponding to the memory address. The row decoder 230 may further activates the row(s), e.g., by selecting and enabling the word line 223 of each selected row. After a row is selected and activated, the logic circuit can perform read or write operations on the memory cells in the row. In some embodiments, the row decoder 230 may further include a row driver for each word line 223 to drive a signal down the word line 223. The row decoder 230 may include a digital circuit that can be used to decode memory addresses, select rows of memory cells, or activate word lines 223. The digital circuit may include one or more logic gates. In some embodiments, the row decoder 230 may include one or more inverters to drive the word line 223.

The column decoder 240 selects which column(s) of memory cells to be accessed based on memory addresses received from a logic circuit, e.g., a circuit in the logic layer 120. The column decoder 240 may decode a column address and activate the corresponding column of memory cells. The column decoder 240 may include a digital circuit that can take the column address as input and generate one or more control signals that activate the corresponding column of memory cells. The digital circuit may include a combination of logic gates, such as AND gates and inverters, to decode the address and generate the necessary control signals. The number of inputs and outputs of the column decoder 240 may depend on the size of the memory array 220. For example, in a memory system with 8 columns, the memory column decoder would have 3 address inputs (since 2\hat{ }3=8) and 8 output signals, each corresponding to a specific column. When a particular column address is provided, the column decoder 240 may activate the corresponding output signal, enabling the memory cells in that column for read or write operations. The row decoder 230 and column decoder 240 can facilitate efficient and accurate access to specific rows of memory cells within the memory array 220 and can support retrieval and storage of data in computer systems.

The buffer 250 temporarily stores data, such as signals received by or generated by the memory device 210. In some embodiments, the buffer 250 may facilitate transmission of signals between the memory device 210 and another memory device 210 or between the memory device 210 and a control circuit. The control circuit may be a peripheral circuit (e.g., the peripheral circuit 140, the peripheral circuit 145, etc.) or a logic circuit in a logic die (e.g., a circuit in the logic layer 120, etc.). The buffer 250 can speed up signal transmission in embodiments where there is a relatively large distance (e.g., 1 micron or greater) between the memory device 210 and the other memory device 210 or between the memory device 210 and the control circuit.

In some embodiments, signals may pass through the buffer 250 before they arrive at the memory array 220. For example, a read request may be sent from a logic circuit, arrive at the memory device 210, then pass through the buffer 250 to the sense amplifier 260, the column decoder 240, the row decoder 230, the memory array 220, or some combination thereof. The read data may travel back from the memory array 220 to the logic circuit through the buffer 250. In an embodiment, the read request may be stored in the buffer temporarily before the read request is transmitted to the sense amplifier 260, the column decoder 240, the row decoder 230, or the memory array 220. Similarly, the read data may be stored in the buffer temporarily before the read data is transmitted to the control circuit.

The sense amplifier 260 may amplify and restore weak signals, e.g., to a more robust and usable level. In some embodiments, for reading data from the memory array 220, the sense amplifier 260 may detect and amplify the small voltage difference between the stored data states, typically representing binary values of 0 and 1. By amplifying this voltage difference, the sense amplifier 260 can enable accurate and reliable data retrieval. In some embodiments (e.g., embodiments having high speed data transmission), the sense amplifier 260 may amplify weak signals to avoid signal degradation and noise during signal propagation so that the signals can be more immune to noise, which can enable more accurate data recovery. The sense amplifier 260 may be a latch-based sense amplifier, differential sense amplifier, dynamic sense amplifier, or other types of sense amplifiers.

Even though not shown in FIG. 2, some or all of the memory devices 210 in the memory device stack may be electrically coupled to each other. In an example, a first memory device 210 may be coupled to a first peripheral circuit in a first memory layer, a second memory device 210 may be coupled to a second peripheral circuit in a second memory layer, and the first peripheral circuit may be coupled to the second peripheral circuit, e.g., through one or more vias extending along the Z axis. For example, a via may have an end connected to the first peripheral circuit and another end connected to the second peripheral circuit.

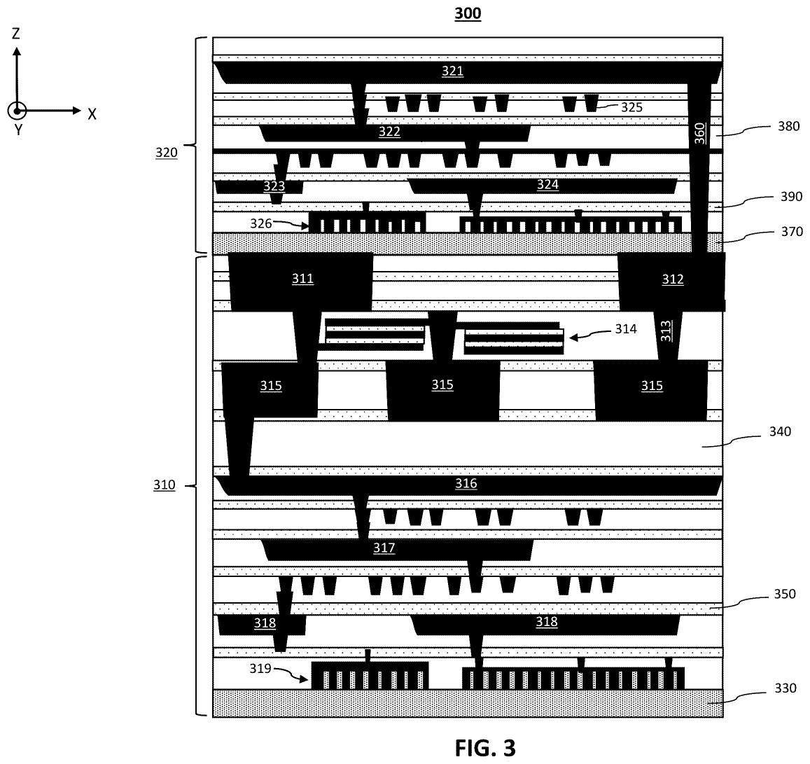

FIG. 3 illustrates an IC device 300 including a logic die 310 with a power interconnect 311 and a signal interconnect 312 for power and signal delivery and a memory die 320 over the logic die, according to some embodiments of the disclosure. The IC device 300 may be an example of a portion of the IC device 100 in FIG. 1. As shown in FIG. 3, the IC device 300 further includes a conductive structure 360. In other embodiments, the IC device 300 may include fewer, more, or different components. For instance, the IC device 200 may include one or more other memory dies over the logic die 310. The IC device 300 may also be referred to as an IC assembly.

In addition to the power interconnect 311 and signal interconnect 312, the logic die 310 further includes vias 313 (individually referred to as “via 313”), two capacitors 314 (individually referred to as “capacitor 314”), interconnects 315, 316, 317, and 318, two interposers 319 (individually referred to as “interposer 319”), a support structure 330, electrical insulator 340, and dielectric layers 350. In other embodiments, the logic die 310 may include fewer, more, or different components. Also, the components in the logic die 310 may be arranged differently.

The support structure 330 may be a semiconductor substrate composed of semiconductor material systems including, for example, N-type or P-type materials systems. In one implementation, the support structure 330 may be a crystalline substrate formed using a bulk silicon or a silicon-on-insulator (SOI) substructure. In other implementations, the support structure 330 may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of Group Ill-V materials (i.e., materials from groups III and V of the periodIC device of elements), Group II-VI (i.e., materials from groups II and IV of the periodIC device of elements), or Group IV materials (i.e., materials from Group IV of the periodIC device of elements). In some embodiments, the support structure 330 may be non-crystalline. In some embodiments, the support structure 330 may be a printed circuit board (PCB) substrate. Although a few examples of materials from which the support structure 330 may be formed are described here, any material that may serve as a foundation upon which IC devices of the logic die 310 as described herein may be built falls within the spirit and scope of the present disclosure.

In some embodiments, the support structure 330 may be in a FEOL section of the logic die 310. The support structure 330 may include one or more semiconductor devices, such as transistors. The transistors may include field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. In some embodiments, the support structure 330 may include one or more semiconductor structures. A semiconductor structure may be a non-planar structure, such as fin, nanoribbon, and so on.

The power interconnect 311 is a conductive structure, such as a metal line. The power interconnect 311 may facilitate power delivery to circuits or devices in the logic die 310 and the memory die 320. The power interconnect 311 may be, or otherwise be coupled to, a power plane. In some embodiments, the power interconnect 311 may be coupled to electrodes of transistors (e.g., electrodes over source regions or over drain regions of transistors) in the logic die 310 and the memory die 320. The power interconnect 311 may be at the same or similar electric potential as the electrodes during the operation of the logic die or the memory die 320.

The capacitors 314 are coupled to the power interconnect 311 to facilitate power delivery. Each capacitor includes conductive layers and dielectric layers. For the purpose of simplicity and illustration, the conductive layers are represented by solid black rectangles and the dielectric layers are represented by dot patterned rectangles in FIG. 3. A conductive layer of capacitor 314 on the left in FIG. 3 may be connected to the power interconnect 311. Another conductive layer of capacitor 314 on the left may be connected to a via 313. The via 313 may also be connected to a conductive layer of capacitor 314 on the right in FIG. 3.

The signal interconnect 312 is also a conductive structure, such as a metal line. The signal interconnect 312 may facilitate signal transmission between the logic die 310 and the memory die 320. The signal interconnect 312 may be coupled to electrodes of transistors (e.g., gate electrodes over channel regions of transistors) in the logic die 310 or the memory die 320. The signal interconnect 312 may be at the same or similar electric potential as the gate electrodes during the operation of the logic die or the memory die 320. In some embodiments, the power interconnect 311 or signal interconnect 312 may be coupled to one or more peripheral circuits in the memory die 310.

The interconnects 315, 316, 317, and 318 are also electrically conductive structures, e.g., metal lines, metal layers, etc. The power interconnect 311, signal interconnect 312, and interconnects 315, 316, 317, and 318 may be in a BEOL section of the logic die 310. The BEOL section may include a plurality of BEOL layers stacked over each other, such as a first BEOL layer including the two interconnects 318 (individually referred to as “interconnect 318”), a second BEOL layer including the interconnect 317, a third BEOL layer including the interconnect 316, a fourth BEOL layer including the three interconnects 315 (individually referred to as “interconnect 315”), and a sixth BEOL layer including the power interconnect 311 and signal interconnect 312.

The vias 313 facilitates electrical connections among the power interconnect 311, signal interconnect 312, and interconnects 315, 316, 317, and 318. A via 313 may be connected to one or more other vias 313 or to one or more interconnects (e.g., one or more of the power interconnect 311, signal interconnect 312, and interconnects 315, 316, 317, and 318). Some of the vias 313 may facilitate power delivery through the power interconnect 311. Some of the vias 313 may facilitate signal transmission from circuits or devices in the support structure 330 to the memory die 320 through the signal interconnect 312. Even though not shown in FIG. 3, the logic die 310 may include one or more vias that are connected to transistors in the support structure 330.

The interposers 319 facilitate electrical connection between the support structure 330 (e.g., transistor in the support structure 330) to components in the BEOL section of the logic die 310. An interposer 319 may include a semiconductor layer (e.g., a silicon layer) and a plurality of TSVs extending from a top surface of the semiconductor layer to the bottom surface of the semiconductor layer. The TSVs may be connected to one or more vias 313 and coupled to one or more interconnects in the BEOL section. In some embodiments, the interposers 319 may be in the FEOL section.

At least some of the conductive components of the logic die 310 (e.g., the power interconnect 311, signal interconnect 312, interconnects 315, 316, 317, and 318, vias 313, etc.) may be separated from each other by the electrical insulator 340. The dielectric layers 350 may also be insulative. In some embodiments, the dielectric layers 350 may be hard masks, which may facilitate formation of the at least some of conductive components of the logic die 310.

The memory die 320 is over the logic die 310 along the Z axis. The memory die 320 includes interconnects 321, 322, 323, and 324, vias 325 (individually referred to as “via 325”), two interposers 326 (individually referred to as “interposer 326”), a support structure 370, electrical insulator 380, and dielectric layers 390. In other embodiments, the memory die 320 may include fewer, more, or different components. Also, the components in the memory die 320 may be arranged differently.

The support structure 370 may be a semiconductor substrate composed of semiconductor material systems including, for example, N-type or P-type materials systems. In one implementation, the support structure 370 may be a crystalline substrate formed using a bulk SOI substructure. In other implementations, the support structure 370 may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of Group Ill-V materials (i.e., materials from groups Ill and V of the periodIC device of elements), Group II-VI (i.e., materials from groups II and IV of the periodIC device of elements), or Group IV materials (i.e., materials from Group IV of the periodIC device of elements). In some embodiments, the support structure 370 may be non-crystalline. In some embodiments, the support structure 370 may be a PCB substrate. Although a few examples of materials from which the support structure 370 may be formed are described here, any material that may serve as a foundation upon which IC devices of the memory die 320 as described herein may be built falls within the spirit and scope of the present disclosure.

In some embodiments, the support structure 370 may be in a FEOL section of the memory die 320. The support structure 370 may include one or more semiconductor devices, such as transistors. The transistors may include FET, such as metal-oxide-semiconductor FET (MOSFET), tunnel FET (TFET), fin-based transistor (e.g., FinFET), nanoribbon-based transistor, nanowire-based transistor, GAA transistor, other types of FET, or a combination of both. In some embodiments, the support structure 370 may include one or more semiconductor structures. A semiconductor structure may be a non-planar structure, such as fin, nanoribbon, and so on.

The interconnects 321, 322, 323, and 324 and vias 325 are electrically conductive structures. The interconnects 321, 322, 323, and 324 may be metal lines. The interconnects 321, 322, 323, and 324 may be in a BEOL section of the memory die 320. The BEOL section may include a plurality of BEOL layers stacked over each other, such as a first BEOL layer including the interconnects 323 and 324, a second BEOL layer including the interconnect 322, and a third BEOL layer including the interconnect 321. The vias 325 facilitates electrical connections among the interconnects 321, 322, 323, and 324. In some embodiments, the memory die 320 may include a different number of BEOL layers, e.g., five, six, etc. A via 325 may be connected to one or more other vias 325 or to one or more interconnects. Even though not shown in FIG. 3, the memory die 320 may include one or more vias that are connected to transistors in the support structure 370.

As shown in FIG. 3, the interconnect 321 is coupled to the signal interconnect 312 in the logic die 310 through the conductive structure 360 and can facilitate signal transmission between the logic die 310 and the memory die 320. The conductive structure 360 has an end connected to the interconnect 321 and another end connected to the signal interconnect 312. In some embodiments, the conductive structure 360 may be connected to one or more other interconnects in one or more other memory dies (not shown in FIG. 3). The conductive structure 360 may be an embodiment of a via 150 in FIG. 1. The conductive structure 360 may be a TSV.

In some embodiments, the conductive structure 360 or another conductive structure may facilitate power delivery from the power interconnect 311. In the embodiments of FIG. 3, power delivery components (e.g., power interconnect, power delivery capacitors, etc.) are present in the logic die 310 but are not present in the memory die 320. Such a design can reduce the number of interconnects (or BEOL layers) needed in the memory die 320 so that the density of memory dies can increase, which can promote the memory storage capacity of an IC device with a limited space.

The interposers 326 facilitate electrical connection between the support structure 330 (e.g., transistor in the support structure 330) to components in the BEOL section of the logic die 310. An interposer 326 may include a semiconductor layer (e.g., a silicon layer) and a plurality of TSVs extending from a top surface of the semiconductor layer to the bottom surface of the semiconductor layer. The TSVs may be connected to one or more vias 313 and coupled to one or more interconnects in the BEOL section. In some embodiments, the interposers 326 may be in the FEOL section.

At least some of the interconnects 321, 322, 323, and 324 and vias 325 may be separated from each other by the electrical insulator 380. The dielectric layers 390 may also be insulative. In some embodiments, the dielectric layers 390 may be hard masks, which may facilitate formation of the at least some of the interconnects 321, 322, 323, and 324 and vias 325.

Even though the memory die 320 is above the logic die 310 in FIG. 3, the memory die 320 or another memory die 320 may be below the logic die 310 in other embodiments. In the embodiments of FIG. 3, the memory die 320 and the logic die 310 has back-to-front attachment, i.e., the backside of the memory die 320 is attached to the frontside of the logic die 310. In other embodiments, the memory die 320 and the logic die 310 may have front-to-front attachment (i.e., the frontside of the memory die 320 is attached to the frontside of the logic die 310), front-to-back attachment (i.e., the frontside of the memory die 320 is attached to the backside of the logic die 310), or back-to-back attachment (i.e., the backside of the memory die 320 is attached to the backside of the logic die 310).

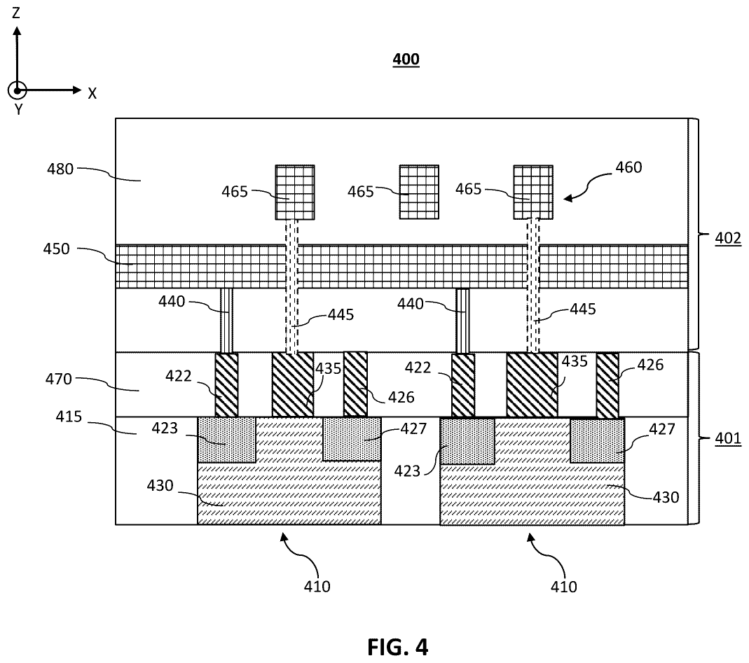

FIG. 4 illustrates an IC device 400 with a FEOL section 401 and a BEOL section 401, according to some embodiments of the disclosure. The IC device 400 may be an embodiment of a portion of a memory layer 110, the logic layer 120, the logic die 310, or the memory die 320. The FEOL section 401 includes transistors 410 (individually referred to as “transistor 410”), a support structure 415, and an electrical insulator 470. The BEOL section 402 includes vias 440 (individually referred to as “via 440”), vias 445 (individually referred to as “via 445”), a metal layer 450, another metal layer 460, and an electrical insulator 480. In other embodiments, the IC device 400 may include fewer, more, or different components. For instance, the IC device 400 may include more transistors, or other semiconductor devices not shown in FIG. 4. Also, the IC device 400 may include a different number of metal layers, vias, or electrical insulators.

The support structure 415 may be any suitable structure, such as a substrate, a die, a wafer, or a chip, based on which the transistors 410 can be built. In some embodiments, the support structure 415 may be a semiconductor substrate composed of semiconductor material systems including, for example, N-type or P-type materials systems, and, in some embodiments, the channel region 430, described herein, may be a part of the support structure 415. In some embodiments, the semiconductor substrate may be a crystalline substrate formed using a bulk SOI substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group Ill-V, Group II-VI, or Group IV materials. In some embodiments, the substrate may be non-crystalline. In some embodiments, the support structure may be a PCB substrate. One or more transistors, such as the transistors 410 may be built on the support structure 415.

Although a few examples of materials from which the support structure 415 may be formed are described here, any material that may serve as a foundation upon which an IC may be built falls within the spirit and scope of the present disclosure. In various embodiments, the support structure 415 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 415 may provide material “support” in that, e.g., the IC devices/structures described herein are build based on the semiconductor materials of the support structure 415. However, in some embodiments, the support structure 415 may provide mechanical support.

A transistor 410 may be an access transistor in a memory cell or a transistor in a control circuit associated with a memory cell. In some embodiments, a transistor 410 may be a FET, such as metal-oxide-semiconductor FET (MOSFET), tunnel FET (TFET), fin-based transistor (e.g., FinFET), nanoribbon-based transistor, nanowire-based transistor, GAA transistor, other types of FET, or a combination of both. The transistor 410 includes a semiconductor structure that includes a channel region 430, a source region 423, and a drain region 427. The transistor 410 includes a semiconductor structure that includes a channel region 430, a source region 423, and a drain region 427. The semiconductor structure of each transistor 410 may be at least partially in the support structure 415. The support structure 415 may include a semiconductor material, from which at least a portion of the semiconductor structure is formed. The semiconductor structure of a transistor 410 (or a portion of the semiconductor structure, e.g., the channel region 430) may be a planar structure or a non-planar structure. A non-planar structure is a three-dimensional structure, such as fin, nanowire, or nanoribbon. A non-planar structure may have a longitudinal axis and a transvers cross section perpendicular to the longitudinal axis. In some embodiments, a dimension of the non-planar structure along the longitudinal axis may be greater than dimensions along other directions, e.g., directions along axes perpendicular to the longitudinal axis.

Each channel region 430 includes a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group Ill of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 400 nm, including all values and ranges therein.

For some example N-type transistor embodiments (i.e., for the embodiments where the transistor 410 is an NMOS (N-type metal-oxide-semiconductor) transistor or an N-type TFET), the channel material may advantageously include a Ill-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 4015 dopant atoms per cubic centimeter (cm⁻³), and advantageously below 40¹³ cm⁻³. These materials may be amorphous or polycrystalline, e.g., having a crystal grain size between 0.5 nanometers and 400 nanometers.

For some example P-type transistor embodiments (i.e., for the embodiments where the transistor 410 is a PMOS (P-type metal-oxide-semiconductor) transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic Ill-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 40¹⁵ cm⁻³, and advantageously below 40¹³ cm⁻³. These materials may be amorphous or polycrystalline, e.g., having a crystal grain size between 0.5 nanometers and 400 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front-end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 4:2:1. In various other examples, IGZO may have a gallium to indium ratio of 4:1, a gallium to indium ratio greater than 4 (e.g., 2:1, 3:1, 4:1, 5:1, 6:1, 7:1, 8:1, 9:1, or 40:1), and/or a gallium to indium ratio less than 4 (e.g., 4:2, 4:3, 4:4, 4:5, 4:6, 4:7, 4:8, 4:9, or 4:10). IGZO can also contain tertiary dopants such as aluminum or nitrogen.

In each transistor 410, the source region 423 and the drain region 427 are connected to the channel region 430. The source region 423 and the drain region 427 each include a semiconductor material with dopants. In some embodiments, the source region 423 and the drain region 427 have the same semiconductor material, which may be the same as the channel material of the channel region 430. A semiconductor material of the source region 423 or the drain region 427 may be a Group IV material, a compound of Group IV materials, a Group Ill/V material, a compound of Group Ill/V materials, a Group II/VI material, a compound of Group II/VI materials, or other semiconductor materials. Example Group II materials include zinc (Zn), cadmium (Cd), and so on. Example Group Ill materials include aluminum (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group Ill/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 423 and the drain region 427 are the same type. In other embodiments, the dopants of the source region 423 and the drain region 427 may be different (e.g., opposite) types. In an example, the source region 423 has N-type dopants and the drain region 427 has P-type dopants. In another example, the source region 423 has P-type dopants and the drain region 427 has N-type dopants. Example N-type dopants include Te, S, As, tin (Sn), Si, Ga, Se, S, In, Al, Cd, chlorine (CI), iodine (1), fluorine (F), and so on. Example P-type dopants include beryllium (Be), Zn, magnesium (Mg), Sn, P, Te, lithium (Li), sodium (Na), Ga, Cd, and so on.

In some embodiments, the source region 423 and the drain region 427 may be highly doped, e.g., with dopant concentrations of about 4·10²¹ cm³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 423 and the drain region 427 may be the regions having dopant concentration higher than in other regions, e.g., higher than a dopant concentration in the channel region 430, and, therefore, may be referred to as “highly doped” (HD) regions.

The channel region 430 may include one or more semiconductor materials with doping concentrations significantly smaller than those of the source region 423 and the drain region 427. For example, in some embodiments, the channel material of the channel region 430 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 423 and the drain region 427, for example below 40¹⁵ cm⁻³ or below 40¹³ cm⁻³. Depending on the context, the term “S/D terminal” may refer to a S/D region or a S/D contact or electrode of a transistor.

A transistor 410 also includes a source electrode 422 over the source region 423 and a drain electrode 426 over the drain region 427. The source electrode 422 is also referred to as a source electrode. The drain electrode 426 is also referred to as a drain electrode. The source electrodes 422 and the drain contacts 446 are electrically conductive and may be coupled to source and drain terminals for receiving electrical signals. A source electrode 422 or the drain electrode 426 includes one or more electrically conductive materials, such as metals. Examples of metals in the source electrodes 422 and the drain contacts 446 may include, but are not limited to, Ruthenium (Ru), copper (Cu), cobalt (Co), palladium (Pd), platinum (Pt), nickel (Ni), and so on.

Each transistor 410 also includes a gate that is over or wraps around at least a portion of the channel region 430. The gate of the transistor 410 includes a gate electrode 435. The gate electrode 435 may also be referred to as a gate electrode. The gate of the transistor 410B includes a gate electrode 435. The gate electrode 435 can be coupled to a gate terminal that controls gate voltages applied on the transistor 410. In some embodiments, the gate electrode 435 may receive signals from a control circuit. The gate electrode may be coupled to a signal interconnect, such as the signal interconnect 312 in FIG. 3.

The gate electrode 435 may include one or more gate electrode materials, where the choice of the gate electrode materials may depend on whether the transistor 410 is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 435 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate of a transistor 410 may also include a gate insulator (not show in FIG. 4) that separates at least a portion of the channel region 430 from the gate electrode so that the channel region 430 is insulated from the gate electrode. In some embodiments, the gate insulator may wrap around at least a portion of the channel region 430. The gate insulator may also wrap around at least a portion of the source region 423 or the drain region 427. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

In the embodiments of FIG. 4, the metal layer 450 is the first metal layer at the frontside. The metal layer 460 is the second metal layer at the frontside and is further from the transistor 410 than the metal layer 450. The metal layer 450 may be referred to as M0, and the metal layer 460 may be referred to as M1. Even though FIG. 4 shows a single metal line in the metal layer 450, the metal layer 450 may include one or more other metal lines. A metal line in the metal layer 450 may have a longitudinal axis along the X axis. The metal layer 460 includes metal lines 465, individually referred to as metal line 465. A metal line may be an electrically conductive structure. A metal line may also be referred to as a conductive line, a metal track, a conductive track, or an interconnect. In some embodiments, a metal line may include one or more metals, such as tungsten (W), molybdenum (Mo), ruthenium (Ru), copper (Cu), other metals, or some combination thereof. Metal lines are shown as rectangles in FIG. 4 for the purpose of simplicity and illustration. A metal line may have different shapes in other embodiments. A metal line may have a transvers cross section perpendicular to its longitudinal axis.

The metal layers 450 and 460 may be electrically coupled to the transistors 410. For instance, the metal layer 450 is coupled to the source electrodes 422 of the transistors 410 through the vias 440. Each via 440 has an end connected to the metal layer 450 and another end connected to a source electrode 422. The metal layer 460 is coupled to the gate electrodes 435 of the transistors 410 through the vias 445. Each via 445 has an end connected to a metal line 465 and another end connected to a gate electrode 435. In some embodiments, the metal layer 450 may facilitate operations of the transistors 410 by providing power to the transistors 410. The metal layer 460 may facilitate operations of the transistors 410 by providing signals to the transistors 410. In some embodiments, the metal layer 450 may function as bit line of a memory array, and the metal layer 460 may function as a word line of a memory array. A via 440 or 445 may include a metal, such as tungsten (W), molybdenum (Mo), ruthenium (Ru), copper (Cu), or other metals. In some embodiments, the IC device 400 may include one or more additional metal layers (not shown in FIG. 4) above the metal layer 460. The IC device 400 may include one or more additional vias connected to the one or more additional metal layer.

The electrical insulators 470 and 480 may separate conductive structures and semiconductor structures in the IC device 400 from each other so that they are shorted to each other. The electrical insulator 470 or 480 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. In some embodiments, a portion of the electrical insulator 470 or 480 may include a first electrical insulator and a second electrical insulator with the second electrical insulator at least partially surrounding the first electrical insulator.

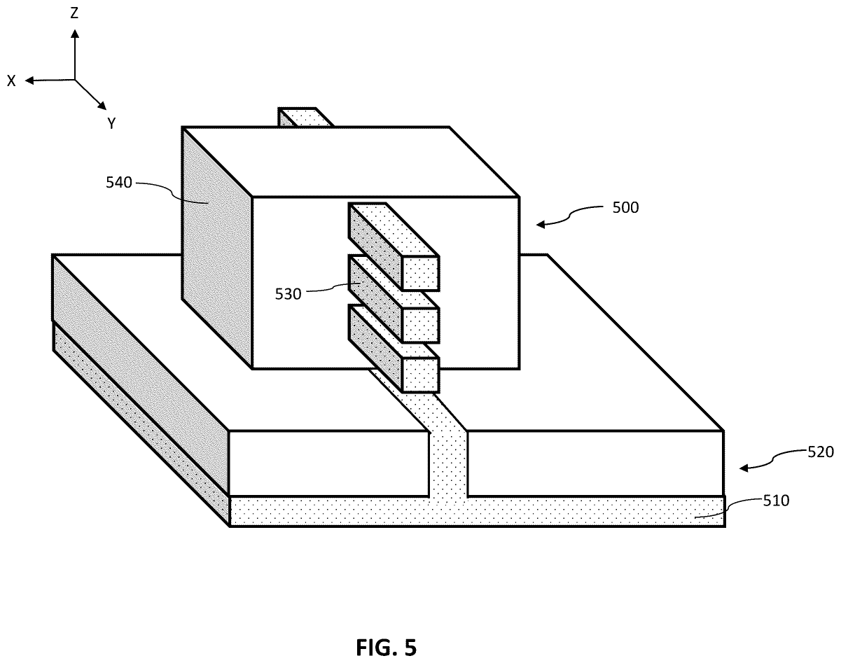

FIG. 5 shows a transistor 500 with nanoribbons, according to some embodiments of the disclosure. The transistor 500 may be an embodiment of a transistor in a logic die (e.g., the logic die 310 in FIG. 3), a memory die (e.g., the memory die 320 in FIG. 3), or the transistors 410 in FIG. 1. The transistor 500 is over a support structure 510 and a dielectric layer 520. The transistor 500 includes a plurality of semiconductor structures 530 (individually referred to as “semiconductor structure 530”), which are stacked over each other along the Z axis, and a gate 540. In other embodiments, the transistor 500 may include fewer, more, or different components. For instance, the transistor 500 may include a different number of semiconductor structures. Semiconductor structures may be arranged differently in the transistor 500. For instance, two or more semiconductor structures may be stacked over each other along the X axis.

The support structure 510 may be any suitable structure, such as a substrate, a die, a wafer, or a chip, based on which transistors can be built. The support structure 510 may be an embodiment of the support structure 415 in FIG. 4. The dielectric layer 520 is over various portions of the support structure 510 along the Z axis. The dielectric layer 520 includes one or more dielectric materials, such as oxide or other low-k dielectric materials. Example oxide in the dielectric layer may include silicon oxide (SiO), silicon oxycarbide (SiOC), silicon oxycarbonitride (SiOCN), and so on.

The semiconductor structures 530 are over the support structure 510. In the embodiments of FIG. 1, the semiconductor structures 530 have a nanoribbon shape with a longitudinal axis substantially parallel to the Y axis and a transverse cross section substantially parallel to the X-Z plane. A dimension of a semiconductor structure 530 along the Y axis may be greater than a dimension of the semiconductor structure 530 in another direction. The semiconductor structures 530 are arranged parallel to each other and are stacked in a direction along the Z axis. In other embodiments, a semiconductor structure 530 may have a different shape, e.g., fin, other non-planar shapes, or a planar shape.

A semiconductor structure 530 may provide the source region, channel region, and drain region of at least one transistor. A channel region of a transistor may include a channel material, such as channel materials described above. The source region and drain region in a transistor are connected to the channel region. The source region and drain region may each include a semiconductor material with dopants. In some embodiments, the source region and drain region have the same semiconductor material, which may be the same as the channel material of the channel region.

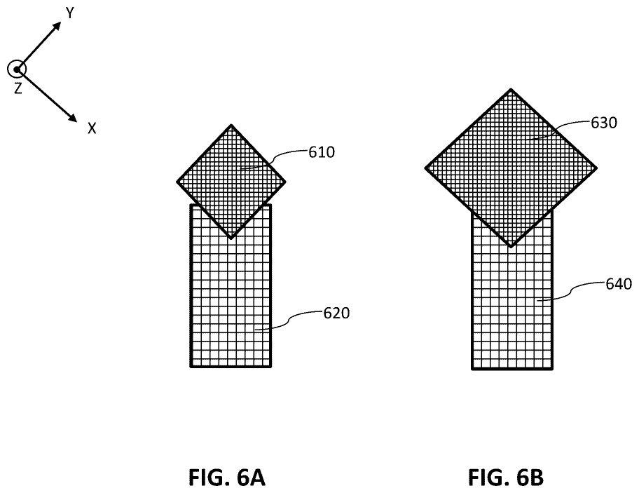

The dimensions of the semiconductor structures 530 may be different for different applications of the transistor 500. For example, compared with embodiments where the transistor 500 is used in a memory die, the cross section of each semiconductor structures 530 in the X-Z plane may be larger when the transistor 500 is used in a logic die. The width of each semiconductor structures 530 along the X axis may also be larger when the transistor 500 is used in a logic die. In some embodiments, the transistor 500 may be used in either a logic layer or a memory layer. A nanoribbon transistor in a logic layer may include more nanoribbons (e.g., approximately one to three times more) than a nanoribbon transistor in a memory layer. In some embodiments, the transistor 500 may be a transistor in a logic layer, and a transistor in a memory layer may be a FinFET. More details regarding dimensions of semiconductor structures in transistors are described below in conjunction with FIGS. 6A and 6B.

The gate 540 is over the dielectric layer 520. In FIG. 5, the gate 540 wraps around the semiconductor structures 530. The gate 540 and the semiconductor structures 530 may form GAA transistors. The gate 540 may include a gate electrode including one or more conductive materials, such as metal, polycrystalline silicon, other types of conductive materials, or some combination thereof. In some embodiments, the choice of the conductive materials in the gate 540 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, the gate 540 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. The gate 540 may also include a gate insulator, part of which may be between the gate electrode and each semiconductor structure 530. The gate 540 may be electrically coupled to a power plane, ground plane, or signal plane for facilitating power supply or signal transmission for the transistor 500.

FIG. 6A illustrates semiconductor regions 610 and 620 of a transistor in a memory die, according to some embodiments of the disclosure. The transistor is also referred to as a memory transistor. The transistor may be an access transistor in a memory cell or a transistor in a peripheral circuit of the memory die. The memory transistor may be an embodiment of the transistors 410 in FIG. 4 or the transistor 500 in FIG. 5. FIG. 6B illustrates semiconductor regions 630 and 640 of a transistor in a logic die, according to some embodiments of the disclosure. The transistor is also referred to as a logic transistor. The logic transistor may be an embodiment of the transistors 410 in FIG. 4 or the transistor 500 in FIG. 5. For the purpose of illustration, FIGS. 6A and 6B do not show other components of the transistors.

As shown in FIG. 6A, the semiconductor region 610 wraps around a portion of the semiconductor region 620. The semiconductor region 610 may be a source region or drain region of the memory transistor. The semiconductor region 620 may be a channel region of the memory transistor. In some embodiments, the semiconductor region 610 (or a semiconductor structure including the semiconductor region 610) may be a non-planar structure, such as a fin or nanoribbon. The semiconductor region 610 can be formed over the semiconductor region 620 through an epitaxy process or a layer transfer process.

In FIG. 6B, the semiconductor region 630 wraps around a portion of the semiconductor region 640. The semiconductor region 630 may be a source region or drain region of the logic transistor. The semiconductor region 640 may be a channel region of the logic transistor. In some embodiments, the semiconductor region 630 (or a semiconductor structure including the semiconductor region 630) may be a non-planar structure, such as a fin or nanoribbon. The semiconductor region 630 can be formed over the semiconductor region 640 through an epitaxy process or a layer transfer process.

In some embodiments, the cross section of the semiconductor region 610 in the X-Y plane is smaller than the cross section of the semiconductor region 630 in the X-Y plane. The width of the semiconductor region 630 along the X axis may be approximately 5% to approximately 50% larger than the width of the semiconductor region 610 along the X axis. For purpose of illustration, the cross section of the semiconductor region 610 in FIG. 6A and the cross section of the semiconductor region 630 in FIG. 6A each has a shape of a parallelogram with sharp corners. In other embodiments, the cross section of the semiconductor region 610 or the semiconductor region 630 can have other shapes, e.g., a curved shape with round corners.

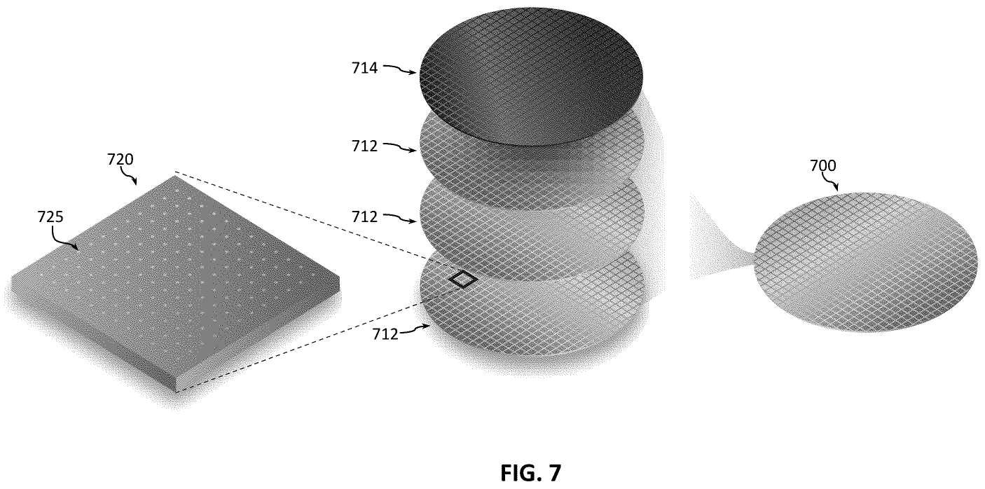

FIG. 7 illustrates an IC device 700 including a stack of wafers, according to some embodiments of the disclosure. The stack of wafers includes wafers 712 (individually referred to as “wafer 712”) and a wafer 714, which may be bonded to one another by hybrid bonding. The wafers 712 may include transistors forming memory cells to implement memory arrays of the IC device 700, while the wafer 714 may include transistors forming control logic configured to control operation of (e.g., to control input/output or read/write to) the memory arrays of the memory cells of the wafers 712. The wafers 712 may be referred to as “memory wafers.” The wafer 714 may be referred to as a “logic wafer,” “compute wafer,” or “compute logic wafer.” The IC device 700 may also be referred to as a compute system, an IC assembly, or an IC device.

Each of the wafers 712 and 714 of the IC device 700 may be composed of one or more semiconductor materials and may include one or more dies having IC structures formed on a surface of the wafers 712 and 714. Each of the dies of the 712 and 714 may be a repeating unit of a semiconductor product that includes any suitable IC, e.g., an IC implementing memory, an IC implementing compute logic, etc. After the fabrication of the semiconductor product is complete (e.g., after manufacture of one or more of the IC structures to be included in microelectronic assemblies as described herein, e.g., ICs included in the wafers 712 and 714 as described herein), the wafers 712 and 714 may undergo a singulation process in which the dies of the wafers 712 and 714 are separated from one another to provide discrete “chips” of the semiconductor product.

In some embodiments, the wafer 714 may include logic circuits used to control the wafers 712—like I/O, memory scheduler etc. As shown in FIG. 7, the die 720 is in a wafer 712. The die 720 may be referred to as a “memory chiplet.” An example memory chiplet may be a memory layer 110 in FIG. 1 or the memory die 320 in FIG. 3. Even though not shown in FIG. 7, analogous dies may be identified in each of the wafers 712 stacked above the bottom memory wafer. Also, one orm ore analogous dies may be identified in the wafer 714. A die in the wafer 714 may be referred to as a “compute chiplet.” An example compute chiplet may be a logic layer 120 in FIG. 1 or the logic die 310 in FIG. 3.

FIG. 7 further illustrates signal vias 725 (individually referred to as “signal via 725”), which may extend in or through the die 720 in order to communicate signals to, from, or between various IC components (e.g., transistors, resistors, capacitors, interconnects, etc.) of the die 720. For example, the signal vias 725 may communicate signals to/from/between transistors implementing memory cells if the die 720 is a memory chiplet, or to, from, or between transistors implementing compute logic if the die 720 is a compute chiplet. In some embodiments, one or more signal vias 725 can extend in or through dies in multiple wafers, e.g., one or more wafers 712, the wafer 714, or some combination thereof. An embodiment of the signal vias 725 is the vias 150 in FIG. 1 or the conductive structure 360 in FIG. 3.

FIG. 8 is an electric circuit diagram of an example memory cell 800, according to some embodiments of the present disclosure. The memory cell 800 may be in a memory array, e.g., the memory array 220 in FIG. 2. In some embodiments, the memory cell 800 may be an SRAM cell used in an SRAM array. As shown in FIG. 8, the memory cell 800 includes transistors M1-M4 for storing a bit value or a memory state (e.g., logic “1” or “0”) of the cell, and two access transistors, M5 and M6, for controlling access to the cell (e.g., access to write information to the cell or access to read information from the memory cell 800). The memory cell 800 is a 6-transistor (6T) memory cell. In other embodiments, the memory cell 800 may include a different number of transistors. Each of the transistors M1-M6 may have any transistor architecture (e.g., planar or non-planar, FinFET, nanoribbon/nanowire, etc.). For example, the transistors M1-M6 may have the transistor architecture shown in FIG. 4. An example of the transistors M1-M6 may be one of the transistors 410 in FIG. 4, the transistor 500 in FIG. 5, the memory transistor in FIG. 6A, or the logic transistor in FIG. 6B.

In the memory cell 800, each bit may be stored on four transistors (M1, M2, M3, M4) that form two cross-coupled inverters 820, each having an input 822 and an output 824. The first inverter 820-1 may be formed by an NMOS transistor M1 and a PMOS transistor M2, while the second inverter 820-2 may be formed by an NMOS transistor M3 and a PMOS transistor M4. As shown in FIG. 8, the gate stack 812-1 of the transistor M1 may be coupled to the gate stack 812-2 of the transistor M2, and both of these gate stacks may be coupled to the input 822-1 of the first inverter 820-1. On the other hand, the first S/D region 814-1 of the transistor M1 may be coupled to the first S/D region 814-2 of the transistor M2, and both of these first S/D regions 814-1 and 814-2 may be coupled to the output 824-1 of the first inverter 820-1. Similarly, for the second inverter 320-2, the gate stack 812-3 of the transistor M3 may be coupled to the gate stack 812-4 of the transistor M4, and both of these gate stacks may be coupled to the input 822-2 of the second inverter 820-2, while the first S/D region 814-3 of the transistor M3 may be coupled to the first S/D region 814-4 of the transistor M4, and both of these first S/D regions 814-3 and 814-4 may be coupled to the output 824-2 of the second inverter 820-2. As also shown in FIG. 8, when the transistors M1 and M3 are NMOS transistors and when the transistors M2 and M4 are PMOS transistors as illustrated in FIG. 8, the second S/D regions 816-1 and 816-3 of the transistors M1 and M3 may be coupled to a ground voltage 832, while the second S/D regions 816-2 and 816-4 of the transistors M2 and M4 may be coupled to a supply voltage 834, e.g., VDD. In the embodiments of the memory cell 800 where the NMOS transistors shown in FIG. 8 are replaced with PMOS transistors and vice versa, the designation of the ground voltage 832 and the supply voltage 834 would be reversed as well, all of which embodiments being within the scope of the present disclosure.

The four transistors M1-M4 in such configuration form a stable storage cell for storing a bit value of 0 or 1. As further shown in FIG. 8, two additional access transistors, M5 an M6, may serve to control the access to the storage cell of the transistors M1-M4 during read and write operations. As shown in FIG. 8, the first S/D region 814-5 of the access transistor M5 may be coupled to the output 824-1 of the first inverter 820-1. Phrased differently, the first S/D region 814-5 of the access transistor M5 may be coupled to each of the first S/D region 814-1 of the transistor M1 and the first S/D region 814-2 of the transistor M2. The second S/D region 816-5 of the access transistor M5 may be coupled to a first bit line 840-1. Thus, each of the first S/D region 814-1 of the transistor M1 and the first S/D region 814-2 of the transistor M2 may be coupled to the first bit line 840-1 (e.g., via the access transistor M5). The gate 812-5 of the access transistor M5 may be coupled to a word line 850.

As further shown in FIG. 8, the first S/D region 814-6 of the access transistor M6 may be coupled to the output 824-2 of the second inverter 820-2. Phrased differently, the first S/D region 814-6 of the access transistor M6 may be coupled to each of the first S/D region 814-3 of the transistor M3 and the first S/D region 814-4 of the transistor M4. The second S/D region 816-6 of the access transistor M6 may be coupled to a second bit line 840-2. Thus, each of the first S/D region 814-3 of the transistor M3 and the first S/D region 814-4 of the transistor M4 may be coupled to the second bit line 840-2 (e.g., via the access transistor M6). The gate 812-6 of the access transistor M6 may be coupled to the word line 850. Thus, the gates 812-5 and 812-6 of both of the access transistors M5 and M6 may be coupled to a single, shared, WL, the word line 850.

As also shown in FIG. 8, the input 822-1 of the first inverter 820-1 may be coupled to the first S/D region 814-6 of the access transistor M6, while the input 822-2 of the second inverter 820-2 may be coupled to the first S/D region 814-5 of the access transistor M5. In other words, each of the gate stack 812-1 of the transistor M1 and the gate stack 812-2 of the transistor M2 may be coupled to the first S/D region 814-6 of the access transistor M6, while each of the gate stack 812-3 of the transistor M3 and the gate stack 812-4 of the transistor M4 may be coupled to the first S/D region 814-5 of the access transistor M5. Phrased differently, each of the gate stack 812-1 of the transistor M1 and the gate stack 812-2 of the transistor M2 may be coupled to the second bit line 840-2 (e.g., via the access transistor M6), while each of the gate stack 812-3 of the transistor M3 and the gate stack 812-4 of the transistor M4 may be coupled to the first bit line 840-1 (e.g., via the access transistor M5).

The word line 850 and the first and second BLs 840 may be used together to read and program (i.e., write to) the memory cell 800. In particular, access to the cell may be enabled by the word line 850 which controls the two access transistors M5 and M6 which, in turn, control whether the memory cell 800 should be connected to the BLs 840-1 and 840-2. During operation of the memory cell 800, a signal on the first bit line 840-1 may be complementary to a signal on the second bit line 840-2. The two BLs 840 may be used to transfer data for both read and write operations. In other embodiments of the memory cell 800, only a single bit line 840 may be used, instead of two bitlines 840-1 and 840-2, although having one signal BL and one inverse, such as the two BLs 840, may help improve noise margins.

During read accesses, the BLs 840 are actively driven high and low by the inverters 820 in the memory cell 800. This may improve SRAM bandwidth compared to DRAM. The symmetric structure of the memory cell 800 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the word line 850 and the BLs 840, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 9 provides a top-down plan view of one example implementation of the memory cell 800 in FIG. 8, according to some embodiments of the present disclosure. FIG. 9 illustrates how the six transistors M1-M6 shown in FIG. 8 may be implemented. Several elements from FIG. 8 are labelled in FIG. 9. For example, the transistors M1-M6 are labelled in FIG. 9, with the approximate boundaries of the individual transistors shown in FIG. 9 with dashed rectangles. Certain elements, e.g., the specific S/D regions 814 and 816 and the gate stacks 812, are not labelled in FIG. 9 in order to not clutter the drawings.

FIG. 9 illustrates that transistors M1 and M5 may be provided along a first region of an N-type semiconductor 902, transistors M2 and M4 may each be provided along a respective first and second region of a P-type semiconductor 904, and the transistors M4 and M6 may be provided along a second region of the N-type semiconductor 902. Each of the regions of the N-type semiconductor 902 and P-type semiconductor 904 may be formed in a support structure (e.g., a substrate) or over a support structure, e.g., as a fin or nanoribbon. The N-type semiconductor 902 is suitable for forming transistors of a first type, e.g., NMOS transistors, while the P-type semiconductor 904 is suitable for forming transistors of a second type, e.g., PMOS transistors, thus realizing NMOS transistors M1, M3, M5, and M6, and PMOS transistors M2 and M4, as shown in FIG. 8.

In the plan view shown in FIG. 9, S/D contacts 906, gate electrodes 908, and interconnects 910 are formed over the N-type and P-type semiconductors 902 and 904, e.g., as layers processed over the N-type and P-type semiconductors 902 and 904. While not specifically shown in FIG. 9, S/D regions may be formed under the S/D contacts 906, and gate dielectrics may be formed under the gate electrodes 908. Any of the materials and processes described with respect to FIG. 4 may be used to form the transistors shown in FIG. 9.

More specifically, a shared gate stack may be used to realize the gate stack 812-1 of the transistor M1 coupled to the gate stack 812-2 of the transistor M2. The shared gate stack is labelled 822-1 in FIG. 9, representing a node that is the input 822-1 of the first inverter 820-1 of the memory cell 800. Similarly, a shared gate stack may be used to realize the gate stack 212-3 of the transistor M3 coupled to the gate stack 812-4 of the transistor M4 3. The shared gate stack is labelled 822-2 in FIG. 9, representing a node that is the input 822-2 of the second inverter 820-2 of the memory cell 800.

As also shown in FIG. 9, a first shared S/D contact may be used to realize the first S/D region 814-1 of the transistor M1 coupled to the first S/D region 814-2 of the transistor M2. The first shared S/D contact is labelled 824-1 in FIG. 9, representing a node that is the output 824-1 of the first inverter 820-1 of the memory cell 800. Similarly, a second shared S/D contact may be used to realize the first S/D region 814-3 of the transistor M3 coupled to the first S/D region 814-4 of the transistor M4. The first shared S/D contact is labelled 824-2 in FIG. 9, representing a node that is the output 824-2 of the second inverter 820-2 of the memory cell 800.

A first interconnect 910-1, shown in FIG. 9, may then be used to couple the shared gate stack 822-1 of the first inverter 820-1 to the shared S/D contact 824-2 of the second inverter 820-2, thus realizing the coupling of the input 822-1 of the first inverter 820-1 to the output 824-2 of the second inverter 820-2, shown in FIG. 8. Similarly, a second interconnect 910-2, shown in FIG. 9, may then be used to couple the shared gate stack 822-2 of the second inverter 820-2 to the shared interconnect 824-1 of the first inverter 820-1, thus realizing the coupling of the input 822-2 of the second inverter 820-2 to the output 824-1 of the first inverter 820-1, shown in FIG. 8.

FIG. 9 further illustrates that, in a given memory cell 800, the first S/D region 814-5 of the transistor M5 may be shared with (e.g., be the same as) the first S/D region 814-1 of the transistor M1 (since both of these transistors are implemented in a single region of the N-type semiconductor 902). In addition, the first S/D region 814-3 of the transistor M3 may be shared with (e.g., be the same as) the first S/D region 814-6 of the transistor M6 (since both of these transistors are implemented in a single region of the N-type semiconductor 902).

Both of the second S/D region 816-1 of the transistor M1 and the second S/D region 816-3 of the transistor M3 may be coupled to the ground voltage 832, as was described with reference to FIG. 8. Both of the second S/D region 816-2 of the transistor M2 and the second S/D region 816-4 of the transistor M4 may be coupled to the supply voltage 834, as was described with reference to FIG. 8.

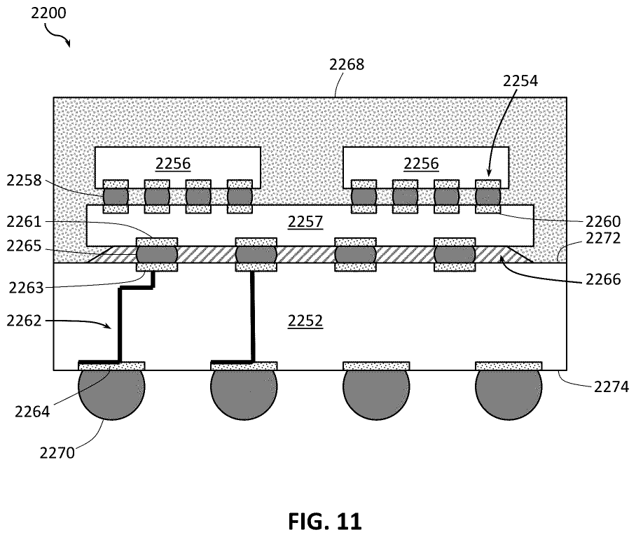

FIGS. 10A and 10B are top views of a wafer 2000 and dies 2002 that can facilitate stacked memory layers with uniform access, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 11. The wafer 2000 may be composed of semiconductor material and may include one or more dies 2002 having IC devices formed on a surface of the wafer 2000. An IC device may be, or may include, the IC device 100, 200, 300, 400, or 700. Each of the dies 2002 may be a repeating unit of a semiconductor product that includes any suitable IC. After the fabrication of the semiconductor product is complete, the wafer 2000 may undergo a singulation process in which each of the dies 2002 is separated from one another to provide discrete “chips” of the semiconductor product. In particular, memory devices as disclosed herein may take or include components that take the form of the wafer 2000 (e.g., not singulated) or the form of the die 2002 (e.g., singulated). The die 2002 may include one or more diodes, one or more transistors (e.g., one or more Ill-N transistors as described herein) as well as, optionally, supporting circuitry to route electrical signals to the Ill-N diodes with n-doped wells and capping layers and Ill-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 11 is a side, cross-sectional view of an example IC package 2200 that may include stacked memory layers with uniform access, according to some embodiments of the disclosure. In some embodiments, the IC package 2200 may be a system-in-package (SiP). An example of the IC package 2200 may include the IC device 100, 200, 300, 400, or 700.

As shown in FIG. 11, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 11 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 11 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

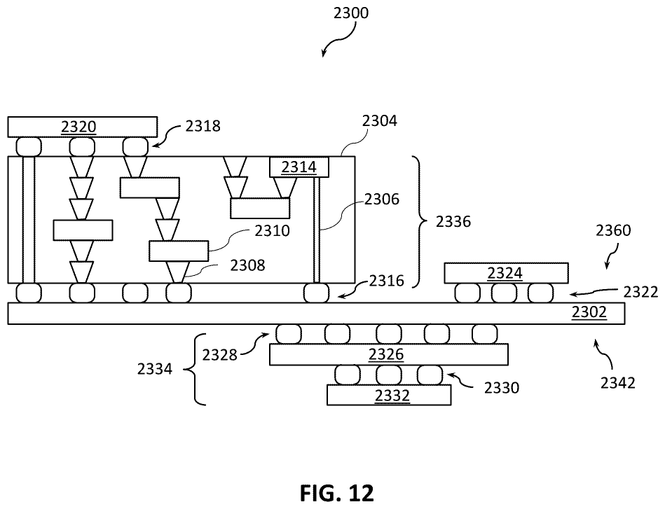

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 11 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 12.

The dies 2256 may take the form of any of the embodiments of the die 2002 discussed herein and may include any of the embodiments of stacked memory layers with uniform access. In embodiments in which the IC package 2200 includes multiple dies 2256, the IC package 2200 may be referred to as a multi-chip package. Importantly, even in such embodiments of an MCP implementation of the IC package 2200, one or more IC devices with stacked memory layers with uniform access may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc. In some embodiments, the dies 2256 may include stacked memory layers with uniform access. In some embodiments, at least some of the dies 2256 may not include any Ill-N diodes with n-doped wells and capping layers.

The IC package 2200 illustrated in FIG. 11 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 11, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 12 is a cross-sectional side view of an IC device assembly 2300 that may include components having stacked memory layers with uniform access, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include stacked memory layers with uniform access in accordance with any of the embodiments disclosed herein; e.g., any of the IC packages discussed below with reference to the IC device assembly 2300 may take the form of any of the embodiments of the IC package 2200 discussed above with reference to FIG. 11 (e.g., may include stacked memory layers with uniform access).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 12 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 11), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 10B), an IC device or system (e.g., the IC device 100, 200, 300, or 700), or any other suitable component. In particular, the IC package 2320 may include stacked memory layers with uniform access as described herein. Although a single IC package 2320 is shown in FIG. 12, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 12, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group Ill-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art. The interposer 2304 may be an embodiment of the interposers 319 or interposers 326 in FIG. 3.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 12 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

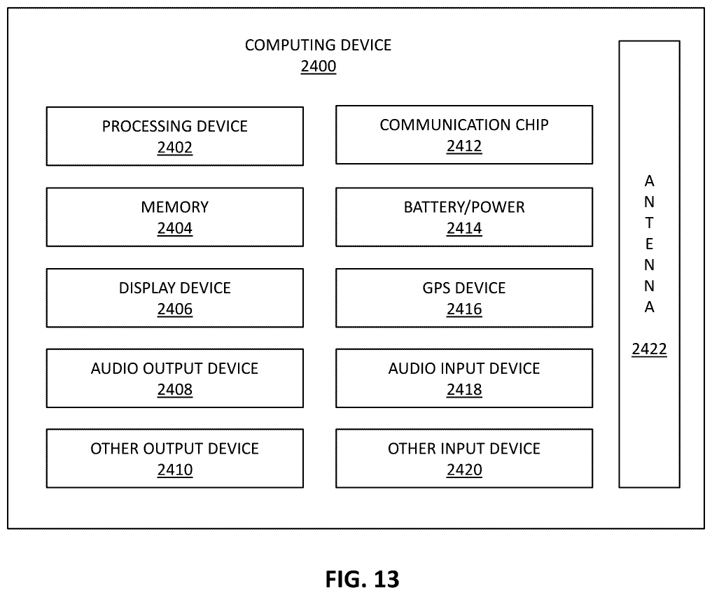

FIG. 13 is a block diagram of an example computing device 2400 that may include one or more components with stacked memory layers with uniform access, according to some embodiments of the disclosure. For example, any suitable ones of the components of the computing device 2400 may include a die (e.g., the die 2002 of FIG. 10B), according to some embodiments of the disclosure. Any of the components of the computing device 2400 may include an IC device or system (e.g., the IC device 100, 200, 300, or 700) and/or an IC package (e.g., the IC package 2200 of FIG. 11). Any of the components of the computing device 2400 may include an IC device assembly (e.g., the IC device assembly 2300 of FIG. 12).

A number of components are illustrated in FIG. 13 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 13, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), CPUs, GPUs, cryptoprocessors (specialized processors that execute cryptographic algorithms within hardware), server processors, or any other suitable processing devices. The computing device 2400 may include a memory 2404, which may itself include one or more memory devices such as SRAM, DRAM, nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., SRAM.

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an integrated circuit (IC) device, including a first layer including a plurality of first memory arrays, and a first peripheral circuit coupled to the plurality of first memory arrays; a second layer over the first layer, the second layer including a plurality of second memory arrays, and a second peripheral circuit coupled to the plurality of second memory arrays; and a third layer over the first layer or the second layer, the third layer including a logic circuit coupled to the first peripheral circuit and to the second peripheral circuit.

Example 2 provides the IC device according to example 1, further including a conductive structure connected to the first peripheral circuit and the logic die, the conductive structure extending from the first layer to the third layer.

Example 3 provides the IC device according to example 2, in which the conductive structure is further connected to the second peripheral circuit.

Example 4 provides the IC device according to example 2 or 3, further including an additional conductive structure connected to the second peripheral circuit and the logic die, the additional conductive structure extending from the second layer to the third layer; and an insulator that separates the additional conductive structure from the conductive structure.

Example 5 provides the IC device according to any one of examples 2-4, in which the conductive structure includes a through-silicon via.

Example 6 provides the IC device according to any one of examples 1-5, in which: a first memory array includes an array of memory cells and a sense amplifier coupled to the memory cells, and an additional first memory array includes an array of additional memory cells and an additional sense amplifier coupled to the additional memory cells.

Example 7 provides the IC device according to example 6, in which the memory cells are arranged in rows or columns, and an individual row or column includes one or more of the memory cells.

Example 8 provides the IC device according to example 7, in which the first memory array further includes a row decoder or a column decoder.

Example 9 provides the IC device according to any one of examples 6-8, in which: the first memory array further includes a buffer coupled to the memory cells, and the additional first memory array further includes a buffer coupled to the additional memory cells.

Example 10 provides the IC device according to any one of examples 1-9, in which the first layer further includes an additional peripheral circuit that is coupled to a subset of the plurality of first memory arrays.

Example 11 provides an integrated circuit (IC) device, including a stack of memory arrays, an individual memory array including memory cells arranged in rows or columns, a decoder coupled to a row of memory cells or to a column of memory cells, a sense amplifier coupled to the memory cells, and a buffer coupled to the memory cells; and a logic die over the stack of memory arrays, the logic die including an integrated circuit coupled to the stack of memory arrays.

Example 12 provides the IC device according to example 11, further including a data transfer path coupled to the buffer and the logic die for transferring data between the buffer and the logic die.

Example 13 provides the IC device according to example 12, in which the data transfer path is further coupled to a buffer in another memory array in the stack of memory arrays.

Example 14 provides the IC device according to any one of examples 11-13, further including a peripheral circuit coupled to the individual memory array, in which the peripheral circuit and the individual memory array are in a layer that is over one or more other memory arrays in the stack of memory arrays.

Example 15 provides the IC device according to example 14, further including an additional memory array in the layer, in which the additional memory array is outside the stack of memory arrays.

Example 16 provides an integrated circuit (IC) device, including a first die, including a first substrate including a first semiconductor structure, the first semiconductor structure having a first cross section and including a semiconductor region of a first transistor in a logic circuit, and a first interconnect over the substrate, the first interconnect coupled to the logic circuit; a second die over the first die, the second die including a second substrate including a second semiconductor structure, the second semiconductor structure having a second cross section and including a semiconductor region of a second transistor in a memory cell, in which the second cross section is smaller than the first cross section, and a second interconnect over the second substrate, the second interconnect coupled to the memory cell; and a conductive structure having a first end and a second end, the first end connected to the first interconnect, and the second end connected to the second interconnect.

Example 17 provides the IC device according to example 16, in which the first die further includes a third interconnect, the third interconnect separated from the first interconnect by an electrical insulator, in which the third interconnect is coupled to a first electrode of the second transistor, the first interconnect is coupled to a second electrode of the second transistor, the first electrode is over a source region or drain region of the second transistor, and the second electrode is over a channel region of the second transistor.

Example 18 provides the IC device according to example 16 or 17, in which the first semiconductor structure includes a first nanoribbon, the second semiconductor includes a second nanoribbon, and a width of the first nanoribbon is larger than a width of the second nanoribbon.

Example 19 provides the IC device according to any one of examples 16-18, in which the second die further includes a plurality of memory arrays, an individual memory array including a plurality of memory cells; and a peripheral circuit coupled to the individual memory array, in which at least part of the peripheral circuit is between two or more of the plurality of memory arrays.

Example 20 provides the IC device according to any one of examples 16-19, further including a third die over the first die, the third die including a third substrate including a third semiconductor structure, the third semiconductor structure having a third cross section and including a semiconductor region of a third transistor in an additional memory cell, in which the third cross section is smaller than the first cross section, and a third interconnect over the third substrate, the third interconnect coupled to the additional memory cell and to the first interconnect.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first layer comprising:
a plurality of first memory arrays, and
a first peripheral circuit coupled to the plurality of first memory arrays;
a second layer over the first layer, the second layer comprising:
a plurality of second memory arrays, and
a second peripheral circuit coupled to the plurality of second memory arrays; and
a third layer over the first layer or the second layer, the third layer comprising a logic circuit coupled to the first peripheral circuit and to the second peripheral circuit.

2. The IC device according to claim 1, further comprising:
a conductive structure connected to the first peripheral circuit and the logic die, the conductive structure extending from the first layer to the third layer.

3. The IC device according to claim 2, wherein the conductive structure is further connected to the second peripheral circuit.

4. The IC device according to claim 2, further comprising:
an additional conductive structure connected to the second peripheral circuit and the logic die, the additional conductive structure extending from the second layer to the third layer; and
an insulator that separates the additional conductive structure from the conductive structure.

5. The IC device according to claim 2, wherein the conductive structure comprises a through-silicon via.

6. The IC device according to claim 1, wherein:
a first memory array comprises an array of memory cells and a sense amplifier coupled to the memory cells, and
an additional first memory array comprises an array of additional memory cells and an additional sense amplifier coupled to the additional memory cells.

7. The IC device according to claim 6, wherein the memory cells are arranged in rows or columns, and an individual row or column comprises one or more of the memory cells.

8. The IC device according to claim 7, wherein the first memory array further comprises a row decoder or a column decoder.

9. The IC device according to claim 6, wherein:
the first memory array further comprises a buffer coupled to the memory cells, and
the additional first memory array further comprises a buffer coupled to the additional memory cells.

10. The IC device according to claim 1, wherein the first layer further comprises an additional peripheral circuit that is coupled to a subset of the plurality of first memory arrays.

11. An integrated circuit (IC) device, comprising:
a stack of memory arrays, an individual memory array comprising:
memory cells arranged in rows or columns,
a decoder coupled to a row of memory cells or to a column of memory cells,
a sense amplifier coupled to the memory cells, and
a buffer coupled to the memory cells; and
a logic die over the stack of memory arrays, the logic die comprising an integrated circuit coupled to the stack of memory arrays.

12. The IC device according to claim 11, further comprising:
a data transfer path coupled to the buffer and the logic die for transferring data between the buffer and the logic die.

13. The IC device according to claim 12, wherein the data transfer path is further coupled to a buffer in another memory array in the stack of memory arrays.

14. The IC device according to claim 11, further comprising:
a peripheral circuit coupled to the individual memory array, wherein the peripheral circuit and the individual memory array are in a layer that is over one or more other memory arrays in the stack of memory arrays.

15. The IC device according to claim 14, further comprising:
an additional memory array in the layer, wherein the additional memory array is outside the stack of memory arrays.

16. An integrated circuit (IC) device, comprising:
a first die, comprising:
a first substrate comprising a first semiconductor structure, the first semiconductor structure having a first cross section and comprising a semiconductor region of a first transistor in a logic circuit, and
a first interconnect over the substrate, the first interconnect coupled to the logic circuit;
a second die over the first die, the second die comprising:
a second substrate comprising a second semiconductor structure, the second semiconductor structure having a second cross section and comprising a semiconductor region of a second transistor in a memory cell, wherein the second cross section is smaller than the first cross section, and
a second interconnect over the second substrate, the second interconnect coupled to the memory cell; and
a conductive structure having a first end and a second end, the first end connected to the first interconnect, and the second end connected to the second interconnect.

17. The IC device according to claim 16, wherein the first die further comprises:
a third interconnect, the third interconnect separated from the first interconnect by an electrical insulator,
wherein the third interconnect is coupled to a first electrode of the second transistor, the first interconnect is coupled to a second electrode of the second transistor, the first electrode is over a source region or drain region of the second transistor, and the second electrode is over a channel region of the second transistor.

18. The IC device according to claim 16, wherein the first semiconductor structure comprises a first nanoribbon, the second semiconductor comprises a second nanoribbon, and a width of the first nanoribbon is larger than a width of the second nanoribbon.

19. The IC device according to claim 16, wherein the second die further comprises:
a plurality of memory arrays, an individual memory array comprising a plurality of memory cells; and
a peripheral circuit coupled to the individual memory array,
wherein at least part of the peripheral circuit is between two or more of the plurality of memory arrays.

20. The IC device according to claim 16, further comprising:
a third die over the first die, the third die comprising:
a third substrate comprising a third semiconductor structure, the third semiconductor structure having a third cross section and comprising a semiconductor region of a third transistor in an additional memory cell, wherein the third cross section is smaller than the first cross section, and
a third interconnect over the third substrate, the third interconnect coupled to the additional memory cell and to the first interconnect.
